(19) United States
(12) Patent Application Publication
(10) Pub. No.: US 2025/0126917 A1
(43) Pub. Date: Apr. 17, 2025

(54) IMAGE SENSOR

(71) Applicant: Samsung Electronics Co., Ltd., Suwon-si (KR)

(72) Inventors: Jonghoon PARK, Suwon-si (KR); Junghyun KIM, Suwon-si (KR); Jungchak AHN, Suwon-si (KR); Yun Ki LEE, Suwon-si (KR); Junsik LEE, Suwon-si (KR)

(73) Assignee: Samsung Electronics Co., Ltd., Suwon-si (KR)

(21) Appl. No.: 18/655,714

(22) Filed: May 6, 2024

(30) Foreign Application Priority Data
Oct. 12, 2023 (KR) 10-2023-0136264

(51) Int. Cl. H01L 27/146

(52) U.S. Cl. CPC H10F 39/807; H10F 39/8063; H10F 39/199

(57) ABSTRACT

An image sensor includes a semiconductor substrate including a plurality of pixels, a first surface, and a second surface, opposing the first surface, and a device isolation layer in a trench penetrating through the first surface and the second surface of the semiconductor substrate and separating the pixels from each other. The device isolation layer may include a conductive separation layer extending from the first surface to the second surface, an insulating liner interposed between the conductive separation layer and the semiconductor substrate, and a capping separation layer extending in a direction from the second surface to the first surface and contacting the conductive separation layer.

### CROSS-REFERENCE TO RELATED APPLICATION(S)

This U.S. non-provisional application claims priority under 35 USC § 119 to Korean Patent Application No. 10-2023-0136264, filed on Oct. 12, 2023, in the Korean Intellectual Property Office, the disclosure of which is herein incorporated by reference in its entirety.

### BACKGROUND

Various example embodiments relate to an image sensor.

An image sensor may include a plurality of pixels that are two-dimensionally arranged. Each of the pixels may include a photodiode as a photoelectric conversion element, and a device isolation layer may be formed between or may define photoelectric conversion elements to separate the photoelectric conversion elements from each other. The device isolation layer may exhibit a light absorption effect depending on a material thereof. Therefore, when light is absorbed on a light-incident side, the intensity of light entering the photoelectric conversion elements may be reduced.

### SUMMARY

Various example embodiments may provide an image sensor that significantly reduce optical loss, which may improve photoelectric conversion efficiency.

Alternatively or additionally various example embodiments may provide an image sensor that significantly reduce optical loss while significantly reducing pixel defects to prevent degradation of the image sensor.

According to some example embodiments, an image sensor includes a semiconductor substrate including a plurality of pixels, a first surface, and a second surface, opposing the first surface, and having a first height, a device isolation layer in a trench penetrating through the first surface and the second surface of the semiconductor substrate and separating the pixels from each other, and a microlens on the second surface. The device isolation layer may include a conductive separation layer with a second height smaller than the first height, a capping separation layer on the conductive separation layer to cover an upper surfaced of the conductive separation layer, and an insulating liner extending in a direction from the first surface to the second surface, contacting the conductive separation layer, and having a height smaller than the first height and greater than or equal to the second height.

Alternatively or additionally according to various example embodiments, an image sensor may include a semiconductor substrate comprising a plurality of pixels, a first surface, and a second surface opposing the first surface, a device isolation layer in a trench penetrating through the first surface and the second surface of the semiconductor substrate and separating the pixels from each other; and a microlens provided on the second surface. Each pixel may comprise a photoelectric conversion element in the semiconductor substrate, and an upper surface of the semiconductor substrate of each pixel separated by the device isolation layer has a lens shape convex on one side, the lens shape configured to refract a path of light incident on the upper surface of the semiconductor substrate such that the light travels to the photoelectric conversion element.

Alternatively or additionally according to various example embodiments, an image sensor may include a semiconductor substrate comprising a plurality of pixels, a first surface, and a second surface opposing the first surface, a device isolation layer in a trench penetrating through the first surface and the second surface of the semiconductor substrate and separating the pixels from each other, and a microlens on the second surface. The trench may define a first trench having a first width and a second trench having a second width greater than the first width. The device isolation layer may include a conductive separation layer within the first trench, a capping separation layer on the conductive separation layer to cover an upper surface of the conductive separation layer and within the second trench, and an insulating liner extending in a direction from the first surface to the second surface and between the semiconductor substrate and the conductive separation layer. An upper surface of the semiconductor substrate of each pixel separated by the device isolation layer has a lens shape convex on one side, the lens shape configured to refract a path of light incident on the upper surface of the semiconductor substrate such that the light travels to the photoelectric conversion element.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a block diagram of an image sensor according to various example embodiments.

FIG. 2 is a plan view illustrating a portion of a pixel array according to some example embodiments.

FIG. 3 is a cross-sectional view taken along line A-A′ of FIG. 2.

FIG. 4 is an enlarged cross-sectional view of portion P1 of FIG. 3.

FIG. 5 is a cross-sectional view illustrating only a semiconductor substrate within a single pixel in an image sensor according to some example embodiments.

FIG. 6A is a cross-sectional view illustrating an image sensor according to some example embodiments, FIG. 6B is an enlarged view of portion P2 of FIG. 6A, and FIG. 6C is a cross-sectional view illustrating only a semiconductor substrate within a single pixel in an image sensor illustrated in FIG. 6A.

FIG. 7A is a cross-sectional view illustrating an image sensor according to some example embodiments, FIG. 7B is an enlarged view of portion P3 of FIG. 7A, and FIG. 7C is a cross-sectional view illustrating only a semiconductor substrate within a single pixel in an image sensor illustrated in FIG. 7A.

FIG. 8 is a cross-sectional view illustrating an image sensor according to some example embodiments.

FIGS. 9 and 10 are cross-sectional views, each illustrating an image sensor according to some example embodiments.

FIG. 11 is a circuit diagram of pixels in an image sensor according to some example embodiments.

FIG. 12 is a plan view illustrating an image sensor according to some example embodiments.

FIGS. 13A to 13E are conceptual plan views illustrating an array of pixels in a pixel array area of FIG. 12.

### DETAILED DESCRIPTION

The present disclosure may be modified in various ways, and may have various embodiments, among which specific example embodiments will be described in detail with reference to the accompanying drawings. However, it should be understood that the description of the specific embodiments of the present disclosure is not intended to limit the present disclosure to a particular mode of practice, and that the disclosure is to cover all modifications, equivalents, and substitutes included in the spirit and technical scope of variously described example embodiments.

Hereinafter, various example embodiments will be described in detail with reference to the attached drawings. Like reference numerals in the drawings denote like elements, and redundant descriptions thereof will be omitted.

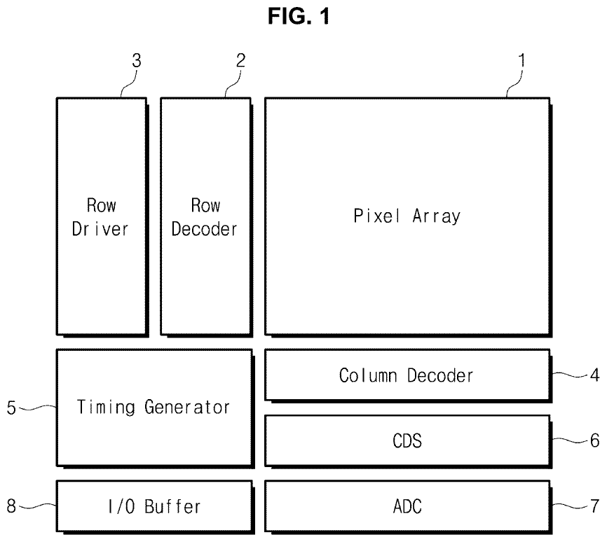

FIG. 1 is a block diagram of an image sensor according to example embodiments.

Referring to FIG. 1, an image sensor according to some example embodiments may include a pixel array 1, a row decoder 2, a row driver 3, a column decoder 4, a timing generator 5, a correlated double sampler (CDS) 6, an analog-to-digital converter (ADC) 7, and an input/output buffer (I/O Buffer) 8.

The pixel array 1 may include a plurality of pixels that are two-dimensionally arranged, and may convert optical signals into electrical signals. The pixel array 1 may be driven by a plurality of driving signals such as one or more of a pixel select signal, a reset signal, and a charge transfer signal from the row driver 3. In some example embodiments, the converted electrical signals may be provided to the correlated double sampler 6.

The row driver 3 may provide a plurality of driving signals to the pixel array 1 to drive a plurality of pixels based on a decoded result from the row decoder 2. When pixels are arranged in a matrix form (such as a rectangular or square form), the driving signals may be provided for each row.

The timing generator 5 may provide a timing signal and a control signal to the row decoder 2 and the column decoder 4.

The correlated double sampler 6 may receive, hold, and sample the electrical signal generated by the pixel array 1. The correlated double sampler 6 may perform a double sampling operation on a specific noise level and on a signal level of the electrical signal to output a difference level corresponding to a difference between the noise level and the signal level.

The analog-to-digital converter 7 may convert analog signals, corresponding to the difference level output from the correlated double sampler 6, into digital signals. The analog-to-digital convert 7 may then output the converted digital signals.

The input/output buffer 8 may latch the digital signals, and the latched digital signals may be sequentially output to a video signal processor, not illustrated, based on the decoded result from the column decoder 4.

Any or all of the elements described with reference to FIG. 1 may communicate with any or all other elements described with reference to FIG. 1. For example, any element may engage in one-way and/or two-way and/or broadcast communication with any or all other elements in FIG. 1, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

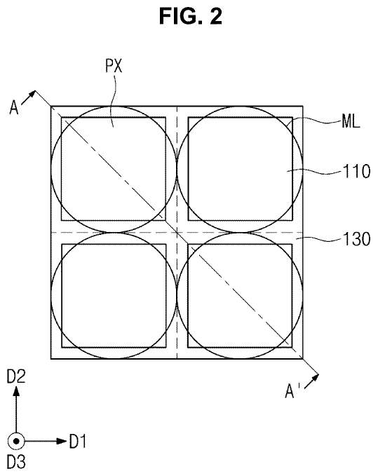

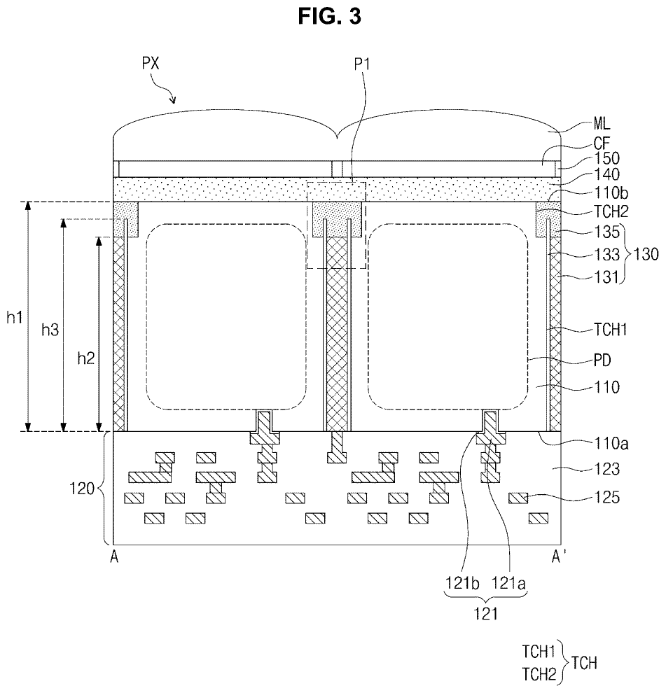

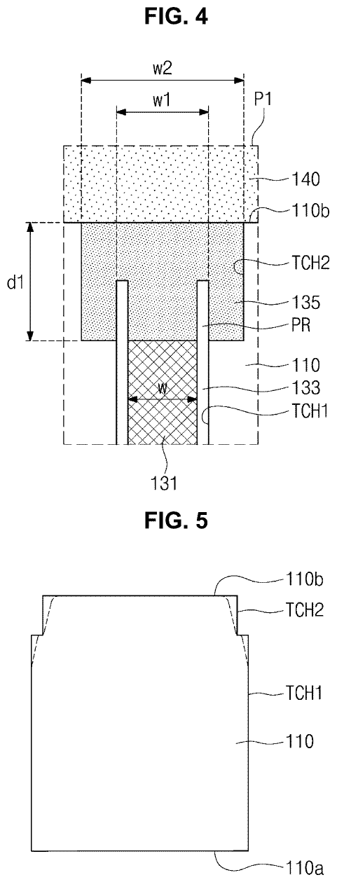

FIG. 2 is a plan view illustrating a portion of a pixel array according to some example embodiments, FIG. 3 is a cross-sectional view taken along line A-A′ of FIG. 2, and FIG. 4 is an enlarged cross-sectional view of portion P1 of FIG. 3. An image sensor according to some example embodiments may include a pixel array of pixels that are two-dimensionally arranged in a matrix form. In this regard, FIG. 2 illustrates four pixels of the pixel array as an example; however, example embodiments are not limited thereto.

Referring to FIGS. 2 to 4, the pixel array of the image sensor according to some example embodiments may include a semiconductor substrate 110 provided with photoelectric conversion elements PD, a circuit interconnection layer 120, a device isolation layer 130, a color filter CF, a fence pattern 150, and a microlens ML.

The semiconductor substrate 110 may have a first surface 110a and a second surface 110b opposing each other. The first surface 110a of the semiconductor substrate 110 may be or may be referred to as or may correspond to a front surface, and the second surface 110b may be or may be referred to as or may correspond to a rear surface. Light may be incident on the second surface 110b of the semiconductor substrate 110. In this case, the second surface 110b may be or may be referred to as a light incident surface.

The semiconductor substrate 110 may include a substrate formed of (or including) various semiconductor materials, for example, one or more of a silicon semiconductor substrate, a germanium semiconductor substrate, or a silicon-germanium semiconductor substrate. The semiconductor substrate 110 may include impurities having a first conductivity type, e.g., at an impurity concentration much greater than impurities of a second conductivity type. Accordingly, the semiconductor substrate 110 may have the first conductivity type. The impurities having the first conductivity type may be group III elements. For example, the impurities having the first conductivity type may include P-type impurities such as at least one of aluminum (Al), boron (B), indium (In), and/or gallium (Ga). In some example embodiments, a concentration of impurities may be constant throughout a thickness direction of the semiconductor substrate 110; however, example embodiments are not limited thereto, and a concentration of impurities may be non-constant (e.g., concave, convex, concave-convex, etc.).

In the semiconductor substrate 110, photoelectric conversion elements PD may be provided for each pixel PX. The photoelectric conversion elements PD may be interposed between the first surface 110a and the second surface 110b of the semiconductor substrate 110. The photoelectric conversion elements PD may be doped regions including impurities having a second conductivity type, opposite to the first conductivity type; e.g., a concentration of impurities of the second conductivity type may be much greater than a concentration of impurities of the first conductivity type. In some example embodiments, the photoelectric conversion elements PD may include a Group V element, and the Group V element may be an impurity having the second conductivity type. Impurities having the second conductivity type may include N-type impurities such as one or more of phosphorus, arsenic, bismuth, and/or antimony.

The photoelectric conversion elements PD may be provided within the semiconductor substrate 110 and may be disposed at a location spaced apart from the second surface 110b.

The circuit interconnection layer 120 may be provided on the first surface 110a of the semiconductor substrate 110. The circuit interconnection layer 120 may include a circuit unit 121 including a gate pattern 121a and a gate insulating pattern 121b.

The gate pattern 121a may be disposed on the first surface 110a of the semiconductor substrate 110. The gate pattern 121a may function as a gate electrode of one or more of a transfer transistor, a source follower transistor, a reset transistor, or a select transistor for driving an image sensor. For example, the gate pattern 121a may include or may correspond to one or more of a transfer gate, a source follower gate, a reset gate, or a select gate. In the drawing, for ease of description, a single gate pattern 121a is illustrated as being disposed in each pixel. However, example embodiments are not limited thereto, and a plurality of gate patterns 121a may be disposed in each pixel. The gate pattern 121a may have a buried gate structure, but example embodiments are not limited thereto. Unlike illustrated in the drawing, the gate pattern 121a may have a planar gate structure. The gate pattern 121a may include a metal material, a metal silicide material, polysilicon, or combinations thereof.

The gate insulating pattern 121b may be interposed between the gate pattern 121a and the semiconductor substrate 110. The gate insulating pattern 121b may include, for example, a silicon-based insulating material such as a silicon oxide, a silicon nitride, and/or a silicon oxynitride and/or a high-dielectric material such as a hafnium oxide and/or an aluminum oxide having a dielectric constant greater than that of silicon oxide.

The circuit interconnection layer 120 may further include a lower insulating layer 123 and an interconnection structure 125. The lower insulating layer 123 may cover the first surface 110a of the semiconductor substrate 110 and may be provided to have a multilayer structure. The lower insulating layer 123 may include, for example, a silicon-based insulating material such as a silicon oxide, a silicon nitride, and/or a silicon oxynitride.

The interconnection structure 125 may be provided within the stacked lower insulating layer 123. The interconnection structure 125 may include an interconnection portion and a via portion. The interconnection portion may be provided in the lower insulating layer 123 and may be electrically connected to one of the impurity-doped regions and the gate pattern 121a. The interconnection portion may be interposed between two adjacent lower insulating layers. The via portion of the interconnection structure 125 may be connected to the interconnection portion through at least one of the lower insulating layers 123. The interconnection structure 125 may receive photoelectric signals output from the photoelectric conversion elements PD. Although the number of layers of interconnection structures 125 is illustrated as five, example embodiments are not limited thereto, and the number of layers of interconnection structures 125 may be more than or less than five. Additionally or alternatively, at least one geometrical and/or electrical property, such as at least one of a thickness, a width, a spacing, or a pitch of different interconnection structures 125 may be the same as, or different from, other interconnection structures 125.

The device isolation layer 130 may be provided within the semiconductor substrate 110, and may separate and partition pixels PX. For example, the device isolation layer 130 may be provided between pixels PX of the semiconductor substrate 110.

The device isolation layer 130 may be provided in a trench TCH, penetrating through the first surface 110a and the second surface 110b of the semiconductor substrate 110, to separate the pixels PX.

The device isolation layer 130 may be provided in a trench TCH, and the trench TCH may be recessed from the first surface 110a of the semiconductor substrate 110. The trench TCH may include a first trench TCH1, extending from the first surface 110a toward the second surface 110b, and a second trench TCH2 extending from the second surface 110b toward the first surface 110a. When viewed in cross section, unlike the first trench TCH1, the second trench TCH2 is recessed only to a depth (e.g., a predetermined depth or, alternatively, a dynamically determined depth) from the second surface 110b of the semiconductor substrate 110 and does not penetrate through the semiconductor substrate 110.

The device isolation layer 130 may include a conductive separation layer 131 extending from the first surface 110a to the second surface 110b, an insulating liner 133 extending from the first surface 110a to the second surface 110b and interposed between the conductive separation layer 131 and the semiconductor substrate 110, and a capping separation layer 135 extending from the second surface 110b to the first surface 110a and contacting the conductive separation layer 131.

A portion of the separation layer 130, for example, the conductive separation layer 131, may be or may correspond to a deep trench isolation (DTI) layer. Another portion of the device isolation layer 130, for example, the capping separation layer 135, may be or may correspond to a device isolation layer formed to have a smaller depth than a deep device isolation.

In some example embodiments, the conductive separation layer 131 may be formed of or may include a conductive material. For example, the conductive separation layer 131 may be formed of or may include a material containing doped polysilicon and/or a metal. A dopant of the doped polysilicon may include an impurity having the first conductivity type and/or an impurity having the second conductivity type. In some example embodiments, the impurity concentrations of impurities of the first conductivity type may be much greater than, or much less than, impurity concentrations of impurities of the second conductivity type. When the conductive separation layer 131 includes a metal, tungsten, aluminum, or the like, may be used. However, example embodiments are not limited thereto, and alternatively or additionally other materials having conductivity such as various metals, alloys thereof, or doped inorganic materials, may also be used.

The conductive layer 131 may be configured to receive a negative bias. For example, a negative bias voltage may be applied to the conductive separation layer 131, serving to stably collect holes near an interface of the conductive separation layer 131 in a region adjacent to the device isolation layer 130. An interconnection may be connected to the first surface 110a and/or the second surface 110b to apply a negative bias voltage to the conductive separation layer 131.

The conductive separation layer 131 may fill the first trench TCH1 penetrating through the first surface 110a and the second surface 110b of the semiconductor substrate 110. However, in the case of the conductive separation layer 131, the light transmittance is low, so that the conductive separation layer 131 is not provided on the light incident surface, for example, a portion close to the second surface 110b, which may significantly reduce the amount of light incident. In some example embodiments, the second trench TCH2 may not be filled with the conductive separation layer 131. The capping separation layer 135 may be provided in the second trench TCH2 formed from a predetermined depth to the second surface 110b.

In some example embodiments, a length of the conductive separation layer 131 in a direction perpendicular to the first surface 110a may be larger than a length of the capping separation layer 135. For example, the length of the conductive separation layer 131 may be at least twice as large as than the length of the capping separation layer 135.

The insulating liner 133 may extend from the first surface 110a to the second surface 110b, and may be provided along a periphery of the conductive separation layer 131. The insulating liner 133 may be provided between the semiconductor substrate 110 and the conductive separation layer 131 to electrically insulate the conductive separation layer 131 and the semiconductor substrate 110. For example, the conductive separation layer 131 may be spaced apart from the semiconductor substrate 110 by the insulating liner 133. Accordingly, the conductive separation layer 131 may be electrically separated from the semiconductor substrate 110 when the image sensor operates.

The insulating liner 133 may include, for example, a silicon-based insulating material (for example, one or more of silicon nitride (Si₃N₄), silicon oxide (SiO₂, silicate), and/or silicon carbon nitride (SiCN)) and/or a high-x dielectric metal oxide (for example, one or more of hafnium oxide (HfOx), zirconium oxide (ZrO₂), titanium oxide (TiO₂), aluminum oxide (Al₂O₃, alumina), or the like).

The insulating liner 133 may cover all side surfaces of the first trench TCH1. The insulating liner 133 may be provided to have a smaller height than the semiconductor substrate 110. The insulating liner 133 may be formed to be at least longer than the conductive separation layer 131 and protrude upwardly of the conductive separation layer 131. For example, the insulating liner 133 may have a protrusion PR protruding upwardly of the second surface 110b from a surface formed by an upper surface of the conductive separation layer 131.

For example, with respect to the first surface 110a, when a distance from the first surface 110a to the second surface 110b is defined as a first height h1, a length of the conductive separation layer 131 in a direction from the first surface 110a to the second surface 110b is defined as a second height h2, and a length of the insulating liner 133 in a direction from the first surface 110a to the second surface 110b is defined as a third height h3, then the second height h2 may be smaller than the first height h1, and the third height h3 may be smaller than the first height h1 and larger than the second height h2.

The insulating liner 133 may be formed of or may include an insulating material such as one or more of a silicon-based insulating material (for example, silicon nitride (Si₃N₄), silicon oxide (SiO₂, silicate), and/or silicon carbon nitride (SiCN)) and/or a high-+dielectric metal oxide (for example, hafnium oxide (HfOx), zirconium oxide (ZrO₂), titanium oxide (TiO₂), aluminum oxide (Al₂O₃, alumina), or the like).

In some example embodiments, the insulating liner 133 is illustrated as being formed as a single layer, but example embodiments are not limited thereto. In some example embodiments, the insulating liner 133 may include a plurality of layers, and the plurality of layers may be formed of or include the same and/or of different materials.

The insulating liner 133 may be formed of or may include a material having a lower refractive index than the semiconductor substrate 110. Accordingly, crosstalk between pixels PX may be prevented or reduced in likelihood of occurrence and/or in impact from occurrence. The conductive separation layer 131 may be spaced apart from the semiconductor substrate 110 by the insulating liner 133. Accordingly, the conductive separation layer 131 may be electrically separated from the semiconductor substrate 110 when the image sensor operates.

The capping separation layer 135 may be provided on the conductive separation layer 131.

The capping separation layer 135 may include or may be formed of a transparent conductive material. For example, the capping separation layer 135 may include a material having a transmittance of about 70% or more, for example, 80% or more, and may simultaneously have high electrical conductivity and low resistance. For example, the capping separation layer 135 may have electrical conductivity of more than 103S/cm and resistance of less than or equal to 10⁻³ Ωcm. A band gap of the material may be larger than a band gap of visible light such that the visible light passes through without being absorbed and may have a band gap of, for example, 3.5 eV (400 nm) or more.

Alternatively or additionally, the capping separation layer 135 may have a refractive index, different from a refractive index of the semiconductor substrate 110. The capping separation layer 135 has a refractive index, from the refractive index of the semiconductor substrate 110, so that an optical path may be refracted at an interface between the capping separation layer 135 and the semiconductor substrate 110. In some example embodiments, the material of the capping separation layer 135 may be selected from a material having a refractive index smaller than the refractive index of the semiconductor substrate 110, or a material having a refractive index larger than the refractive index of the semiconductor substrate 110.

The material of the capping separation layer 135 is not limited to a specific material. For example, the capping separation layer 135 may be formed of or may include a material including at least one of an organic insulating material and an inorganic insulating material. The capping separation layer 135 may include at least one of silicon oxide, hafnium oxide, silicon nitride, silicon carbonitride, zirconium oxide, aluminum oxide, titanium oxide, tantalum oxide, lanthanum oxide, praseodymium oxide, cerium oxide, neodymium oxide, promethium oxide, samarium oxide, europium oxide, gadolinium oxide, terbium oxide, dysprosium oxide, erbium oxide, holmium oxide, thulium oxide, ytterbium oxide, lutetium oxide, yttrium oxide, aluminum nitride, hafnium nitride, or aluminum oxynitride. In some example embodiments, the capping separation layer may include a silicon oxide or a hafnium oxide.

The capping separation layer 135 may be formed within the second trench TCH2 formed by removing the conductive separation layer 131 and a portion of the semiconductor substrate 110 adjacent to the conductive separation layer 131. In this case, a length or a diameter of the second trench TCH2 provided with the capping separation layer 135 may be larger than a length or a diameter of the first trench TCH1 provided with the conductive separation layer 131. For example, the capping separation layer 135 may be provided with a width larger than a width w of the conductive separation layer 131, or larger than the sum of widths of the conductive separation layer 131 and the insulation liner 133. For example, when the sum of the widths of the conductive separation layer 131 and the insulation liner 133 is referred to as a first width w1 and a width of the capping separation layer 135 is referred to as a second width w2, the second width w2 may be larger than the first width w1.

A lower surface of the capping separation layer 135 may be in contact with or in direct contact with an upper surface of the conductive separation layer 131. As described above, the width of the capping separation layer 135 is formed to have a larger width than the conductive separation layer 131 and the lower surface of the capping separation layer 135 is provided in direct contact with the upper surface of the conductive separation layer 131, and thus the capping separation layer 135 may completely cover the upper surface of the conductive separation layer 131.

The capping separation layer 135 is formed to have a larger width than the lower conductive separation layer 131 and the insulating liner 133, so that the protrusion PR protruding upwardly of at least a portion of the insulating liner 133, for example, the conductive separation layer 131 may be disposed in the capping separation layer 135.

In some example embodiments, the device isolation layer 130 may be formed in various forms and/or in various manners. According to some example embodiments, the device isolation layer 130 may undergo processes of forming a first trench TCH1 from the first surface 110a to the second surface 110b, conformally forming an insulating liner 133 within the first trench TCH1, filling the first trench TCH1 with a material of a conductive separation layer 131, and inverting and removing a portion of the semiconductor substrate 110 on a side of the second surface 110b, e.g., through chemical mechanical polishing (CMP) and/or an etch back process.

In some example embodiments, before inverting the second surface 110b may be passivated, e.g., and may have a film such as a hard-mask and/or photoresist deposited thereon. Then, a second trench TCH2 may be formed through a process such as etching (such as an isotropic etching), and a capping separation layer 135 may fill the second trench TCH2. When the second trench TCH2 is formed, an etching process may be performed to remove portions of the conductive separation layer 131 and the semiconductor substrate 110 and the insulation liner 133 may be etched or remain without being etched.

In the above processes, residues may be generated on a surface of the conductive separation layer 131 by the chemical mechanical polishing and/or the blanket etching. When the residues on the surface of the conductive separation layer 131 are present between the conductive separation layer 131 and the semiconductor substrate 110, it may be difficult to electrically insulate the conductive separation layer 131 and the semiconductor substrate 110, and charges may be accumulated by a bias applied to the conductive separation layer 131, which may cause image degradation. In various example embodiments, the image sensor may effectively cover the surface of the conductive separation layer 131, exposed during a manufacturing process using the capping separation layer 135, to inhibit or reduce the likelihood of electrons from the conductive separation layer 131 from moving to a side of the semiconductor substrate 110, for example, a side of the photoelectric conversion element PD. As a result, the image degradation may be significantly reduced. The insulating liner 133 may have the protrusion PR to separate the conductive separation layer 131 and the semiconductor substrate 110 other without contacting each other. As a result, the electrical insulation between the conductive separation layer 131 and the semiconductor substrate 110 may be facilitated or improved upon.

Color filters CF may be provided on the semiconductor substrate 110 on which the photoelectric conversion elements PD and the separation layer 130 are formed.

The color filters CF may be disposed for each pixel PX on the second surface 110b of the semiconductor substrate 110. For example, the color filters CF may be provided at locations corresponding to the photoelectric conversion elements PD. Each of the color filters CF may be selected as one of a plurality of reference colors. A plurality of standard colors may include, for example, red-green-blue (RGB), red-green-blue-white (RGBW), cyan-magenta-yellow (CMY), cyan-magenta-yellow-black (CMYK), red-yellow-blue (RYB), and RGB IR ray (RGBIR). For example, the color filters CF may be arranged in a Bayer pattern. However, colors of the color filters CF are not limited thereto, and filters of other colors may be provided. The color filters CF may constitute color filter arrays.

A fence pattern 150 may be disposed on the device separation layer 130. For example, the fence pattern 150 may vertically overlap the device isolation layer 130. The fence pattern 150 may have a planar shape corresponding to a shape of the device isolation layer 130. For example, when viewed in plan view, the fence pattern 150 may have a grid shape. When viewed in plan view, the fence pattern 150 may surround the color filters CF. The fence pattern 150 may be interposed between two adjacent color filters CF. The plurality of color filters CF may be physically and optically separated from each other by the fence pattern 150. The fence pattern 150 may include a low refractive index material. The low refractive index material may include a polymer and silica nanoparticles within the polymer. Low refractive index materials may have insulating properties. Alternatively or additionally, the fence pattern 150 may include metal and/or metal nitride. For example, the fence pattern 150 may include titanium and/or titanium nitride.

An upper insulating layer 140 may be interposed between the semiconductor substrate 110 and the color filters CF and between the device isolation layer 130 and the fence pattern 150. The upper insulating layer 140 may cover the second surface 110b of the semiconductor substrate 110 and an upper surface of the device isolation layer 130. The upper insulating layer 140 may include a plurality of layers. For example, the upper insulating layer 140 may include an antireflective layer.

In some example embodiments, at least a portion of the upper insulating layer 140 may include the same material or at least one same material as the capping separation layer 135. In this case, at least a portion of the capping separation layer 135 and the upper insulating layer 140 may be formed using the same material in a single process such as deposition such as an in-situ deposition. In this case, the capping separation layer 135 may be more easily formed simultaneously in a subsequent process of forming the upper insulating layer 140 without a need to additionally form the capping separation layer 135. However, the material of the upper insulating layer 140 is not limited thereto, and the upper insulating layer 140 may be individually formed using a material, different from that of the capping separation layer 135, through a different process.

For example, the upper insulating layer 140 may further include an insulating pattern layer having a high-x dielectric constant greater than that of silicon oxide. The insulating pattern layer may be formed of or may include a material having a dielectric constant that is substantially the same as or higher than that of the insulating liner 133. Materials for the insulating pattern layer may include, for example, one or more of a silicon nitride, a silicon oxide, a silicon carbon nitride, and/or a high-x dielectric metal oxide. The high-x dielectric metal oxide may include, for example, one or more of hafnium oxide, zirconium oxide, aluminum oxide, titanium oxide, tantalum oxide, lanthanum oxide, praseodymium oxide, cerium oxide, neodymium oxide, promethium oxide, samarium oxide, europium oxide, gadolinium oxide, terbium oxide, dysprosium oxide, erbium oxide, holmium oxide, thulium oxide, ytterbium oxide, lutetium oxide, yttrium oxide, aluminum nitride, hafnium nitride, aluminum oxynitride, or the like. Such a high-x dielectric constant may be used to significantly suppress or reduce generation of abnormal charges on the second surface 110b of the semiconductor substrate 110.

The microlens ML may be disposed on the second surface 110b of the semiconductor substrate 110. For example, the microlens ML may be disposed on the color filters CF and the fence pattern 150. The microlens ML may include a lens pattern and a planarized portion. The planarized portion of the microlens ML may be provided on the color filters CF. A lens pattern may be provided on the planarized portion. The lens pattern may be formed to be integrated with the planarized portion and may be connected to the planarized portion without an interface. The lens pattern may include or may be formed of the same material as the planarized portion. As another example, the planarized portion may be omitted, and the lens pattern may be disposed directly on the color filters CF. The lens pattern may be hemispherical. The lens pattern may focus incident light. Lens patterns may be provided at locations corresponding to the photoelectric conversion elements PD of the semiconductor substrate 110. For example, a lens pattern may be provided on the photoelectric conversion device PD in a pixel (PX) area of the semiconductor substrate 110.

The microlens ML may be transparent and transmit light. The microlens ML may include an organic material such as a polymer. For example, the microlens ML may include a photoresist material and/or a thermosetting resin.

In some example embodiments, the color filters CF, the fence patterns 150, and/or the microlenses ML have been described as being provided at overlapping locations corresponding to respective pixels PX, but example embodiments are not limited thereto. At least one of the color filters CF, the fence patterns 150, and the microlenses ML may have an offset structure shifted from a location corresponding to each pixel PX by a predetermined degree. Such an offset structure may result from a process margin of the color filters CF, the fence patterns 150, and/or the microlenses ML, or may be intentionally selected to optimize or improve upon an optical path in consideration of an angle of light traveling from the outside to the pixel PX, or the like.

The image sensor having the above-described structure may significantly reduce the amount of light incident on the photoelectric conversion element PD by removing a portion of the conductive separating layer 131, having a relatively high light absorption rate and a lower light transmittance, from a side where light is incident on the photoelectric conversion element PD.

This will now be described in greater detail. The conductive separation layer 131 may be formed of or may include a conductive material, for example, doped polysilicon. The conductive separation layer 131 formed of polysilicon may absorb incident light, and thus the amount of light entering the photoelectric conversion element PD may be reduced. In some example embodiments, the conductive separation layer 131 within a particular depth, e.g., a predetermined depth may be removed from the second surface 110b on which light is incident, and the capping separation layer 135 may be formed instead. The capping separation layer 135 is formed of a transparent material, so that the transparent material does not absorb light and may significantly reduce a loss of light entering the photoelectric conversion element PD. Accordingly, the amount of light provided to the photoelectric conversion element PD may be increased.

Alternatively or additionally, the conductive separation layer 131 may be applied with a negative bias, serving to collect holes more stably near the interface of the conductive separation layer 131 in an area adjacent to the device separation layer 130. A defect such as dark current can be reduced, and the sensitivity of the image sensor may be increased.

Alternatively or additionally according to some example embodiments, a focusing effect may be obtained by the device isolation layer. This will now be described in detail with reference to FIG. 5.

FIG. 5 is a cross-sectional view illustrating only a semiconductor substrate within a single pixel in an image sensor according to some example embodiments.

Referring to FIGS. 3 to 5, a semiconductor substrate corresponding to each pixel may be patterned in a shape allowing focusing during the formation of the device isolation layer. For example, the semiconductor substrate may be patterned in an upwardly convex shape to refract a path of light, incident on an upper surface of the semiconductor substrate, such that the light travels in a direction of a photoelectric conversion element.

In the image sensor according to various example embodiments, the device isolation layer 130 may be formed to be wider near the second surface 110b, so that a shape of the semiconductor substrate 110 in each pixel PX may be upwardly convex. For example, the device isolation layer 130 has a larger width near the second surface 110b than near the first surface 110a, and therefore the semiconductor substrate 110 may have a smaller width near the second surface 110b than near the first surface 110a. Alternatively or additionally, in the actual fabrication of an image sensor, there may be a difference based on a process margin when patterning is performed through a process such as etching. Therefore, the semiconductor substrate 110 may have a certain degree of slope and curvature as indicated by dashed lines, rather than a straight-line structure, as illustrated in the drawing when viewed in cross-section.

As a result, a shape of the upper surface of the semiconductor substrate 110 may be a rectangular shape with at least some rounded or beveled corners, rather than a completely angular shape. Such a difference in shape may affect the refraction of light passing between the semiconductor substrate 110 and the device isolation layer 130. For example, when a semiconductor substrate is formed to be upwardly convex as in various example embodiments, the semiconductor substrate may function as a convex lens.

In conclusion, the width of the semiconductor substrate 110 according to some example embodiments may be controlled such that the refracted light is directed, as much as possible, toward the photoelectric conversion element PD. To this end, the width of the device isolation layer 130 may be changed. When the semiconductor substrate 110 is manufactured to have a shape substantially similar to a shape of a convex lens through a change in the shape of the device isolation layer 130, a focus of the convex lens may be set to be placed within the photoelectric conversion element PD as much as possible.

As described above, according to some example embodiments, the upper surface of the semiconductor substrate 110 of each pixel PX separated by the device isolation layer 130 has a convex lens shape with an upwardly convex upper surface, so that the amount of light incident on the photoelectric conversion element PD may be significantly reduced. As a result, the sensitivity of the image sensor may be improved.

According to some example embodiments, a device isolation layer may be modified in a variety of ways within the inventive concept of the present disclosure. Example embodiments to be described later are some of the various modifications within the inventive concept of the present disclosure, and can be combined with each other within the limit of compatibility. In the following example embodiments, differences from the above-described embodiment will be mainly described for ease of description.

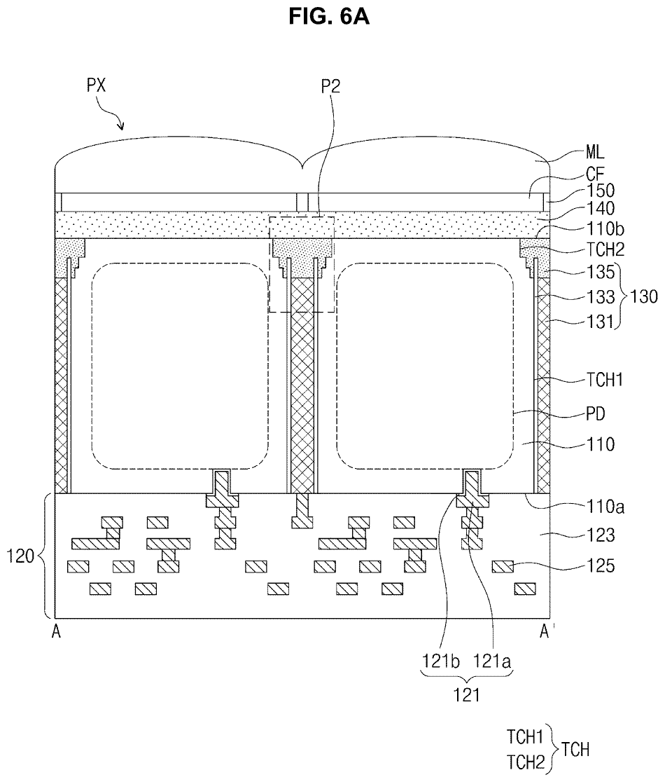

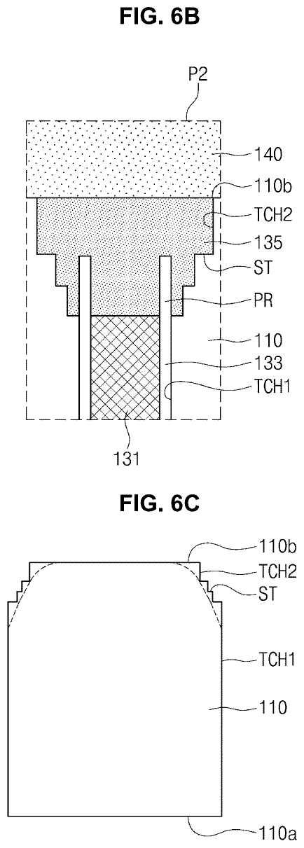

FIG. 6A is a cross-sectional view illustrating an image sensor according to some example embodiments, FIG. 6B is an enlarged view of portion P2 of FIG. 6A, and FIG. 6C is a cross-sectional view illustrating only a semiconductor substrate within a single pixel in an image sensor illustrated in FIG. 6A.

Referring to FIGS. 6A to 6C, a capping separation layer 135 may have a staircase shape in which a width is gradually increased in a direction toward a second surface 110b when viewed in cross-section.

The capping separation layer 135 may be formed by etching a second trench TCH2 to have a shape with a plurality of staircases on a semiconductor substrate 110, and then filling the second trench TCH2 with a material of the capping separation layer 135.

In some example embodiments, the second trench TCH2 may have three staircases as illustrated. In some example embodiments, the second trench TCH2 may have more than three staircases. In the second trench TCH2, a distance between facing staircases ST may be increased in an upward direction, for example, in a direction toward the second surface 110b. As a result, the capping separation layer 135 may also have a width increased in the upward direction, for example, in the direction toward the second surface 110b.

In some example embodiments, similarly to the above-described example embodiment, the device separation layer 130 has a larger width in a portion close to the second surface 110b than in a portion close to the first surface 110a, so that the semiconductor substrate 110 may have a smaller width in the portion close to the second surface 110b than in the portion close to the first surface 110a. Alternatively or additionally, in the actual fabrication of an image sensor, there is a difference based on a process margin when patterning is performed through a process such as etching. Therefore, the semiconductor substrate 110 may have a certain degree of slope and curvature as indicated by dashed lines, rather than a straight-line structure, as illustrated in the drawing when viewed in cross-section. As a result, in some example embodiments, the semiconductor substrate 110 may have an upwardly convex lens shape for each pixel PX. Due to such a shape, light passing between the semiconductor substrate 110 and the device separator 130 may travel to a side of the photoelectric conversion element PD.

In some example embodiments, heights and/or widths of the staircases ST may be the same or different from each other. The heights and/or widths of the staircases ST may be changed in a variety of ways such that refracted light is directed, as much as possible, towards the photoelectric conversion element PD.

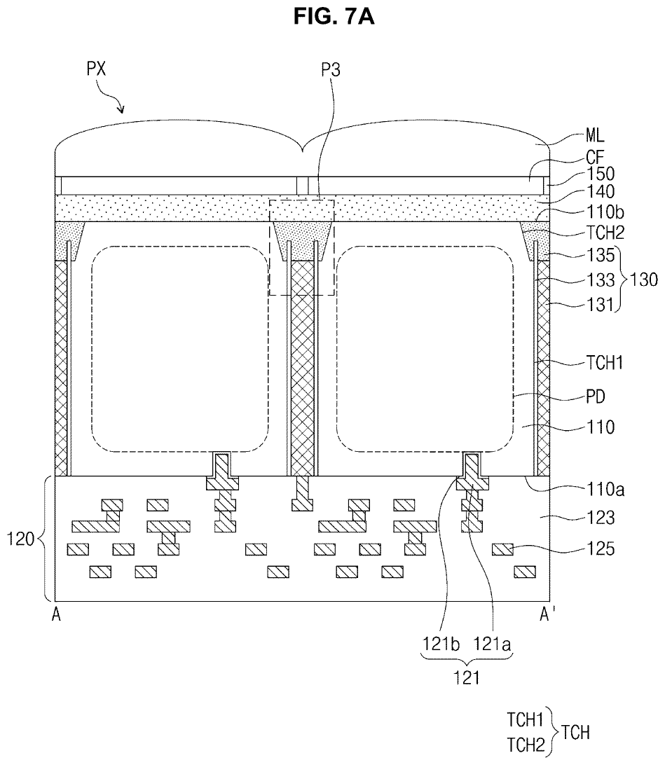

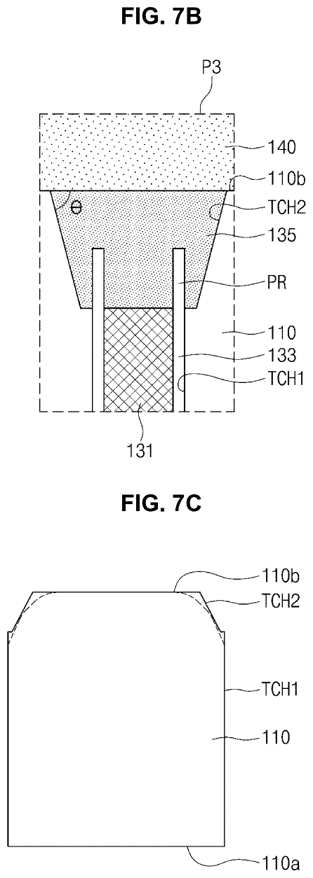

FIG. 7A is a cross-sectional view illustrating an image sensor according to some example embodiments, FIG. 7B is an enlarged view of portion P3 of FIG. 7A, and FIG. 7C is a cross-sectional view illustrating only a semiconductor substrate within a single pixel in an image sensor illustrated in FIG. 7A.

Referring to FIGS. 7A to 7C, a capping separation layer 135 may have an inclined portion having a width increased in a direction toward a second surface 110b when viewed in cross-section.

The capping separation layer 135 may be formed by etching a second trench TCH2 to have an inclined portion when the second trench TCH2 is formed on a semiconductor substrate 110, and then filling the second trench TCH2 with a material of the capping separation layer 135.

In some example embodiments, the second trench TCH2 may have an inclined surface having a predetermined angle θ with respect to the second surface 110b. In some example embodiments, the second trench TCH2 may have a plurality of inclined surfaces having sequentially different angles with respect to the second surface 110b.

In the second trench TCH2 filled with the capping separation layer 135, a distance between the facing staircases ST may be increased in an upward direction, for example, a direction toward the second surface 110b. As a result, the capping separation layer 135 may also have a width increased in an upward direction, for example, a direction toward the second surface 110b.

Due to the inclined surface, the semiconductor substrate 110 corresponding to each pixel PX may have an upwardly convex lens shape. In this case, the number of inclined surfaces, an angle at which the inclined surface intersects the second surface 110b, and a size of the inclined surface may be changed in a variety of ways such that refracted light is directed, as much as possible, towards the photoelectric conversion element PD.

In some example embodiments, the semiconductor substrate 110 may have an upwardly convex lens shape for each pixel PX. Due to such a shape, light passing between the semiconductor substrate 110 and the device isolation layer 130 may travel to a side of the photoelectric conversion element PD.

In some example embodiments, the device isolation layer 130 may be provided in a form different from the above-described embodiment.

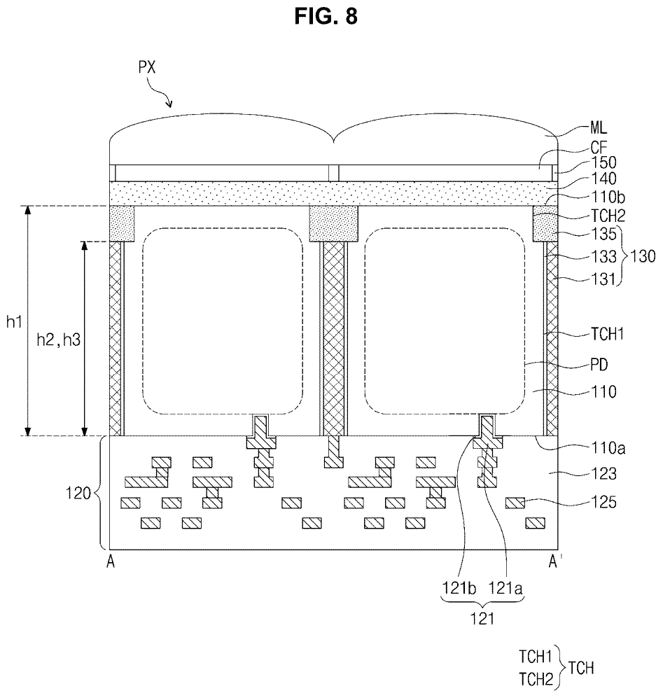

FIG. 8 is a cross-sectional view illustrating an image sensor according to some example embodiments.

Referring to FIG. 8, an insulating liner 133 may be formed to have the same length as a conductive separation layer 131. For example, heights of the insulating liner 133 and the conductive separation layer 131 in a direction from a first surface 110a to a second surface 110b may be the same, and a protrusion PR of the insulating liner 133, protruding inwardly of the capping separation layer 135, may not be provided in the present embodiment.

Referring to the first surface 110a, when a distance from the first surface 110a to the second surface 110b is defined as a first height h1, a length of the conductive separation layer 131 in the direction from the first surface 110a to the second surface 110b is defined as a second height h2, and a length of the insulating liner 133 in a direction from the first surface 110a to the second surface 110b is defined as a third height h3, then the second height h2 may be smaller less than the first height h1 and the third height h3 may be the same as the second height h2.

In the some example embodiments, the conductive separation layer 131 may be provided in a first trench TCH1 and the capping separation layer 135 may be provided in the second trench TCH2 having a larger width than the first trench TCH1. Therefore, similarly to the above-described example embodiment, the semiconductor substrate 110 of each pixel PX may have an upwardly convex lens. As a result, even the present embodiment, a focusing effect based on the shape of the semiconductor substrate 110 may be obtained.

Referring to FIG. 8, the capping separation layer 135 does not include staircases. However, in some example embodiments, the capping separation layer 135 may include staircases in a form, similar to that in FIGS. 6A and 6B. Additionally, in example embodiments illustrated in FIG. 8, the capping separation layer 135 does not include an inclined surface. However, in some example embodiments, the capping separation layer 135 may alternatively or additionally include an included surface in a form, similar to that in FIGS. 7A and 7B.

Due to the shape of the capping separation layer 135 having a larger width than the conductive separation layer 131, the semiconductor substrate 110 corresponding to each pixel PX may have an upwardly convex lens shape. As a result, light refracted and incident on the semiconductor substrate 110 may be directed towards the photoelectric conversion element PD as much as possible.

The image sensor according to some example embodiments may further include a component to prevent or reduce defects that may occur due to an etching process performed during the formation of the capping separation layer.

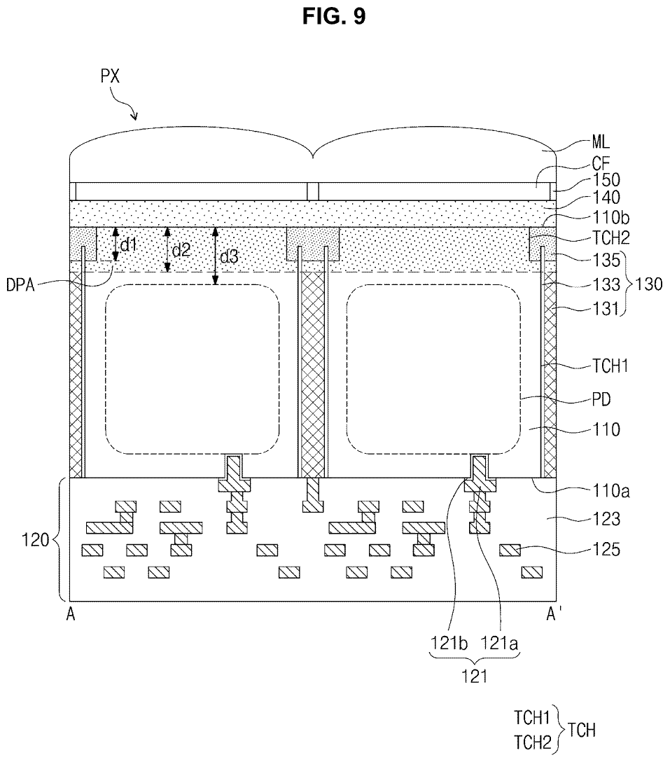

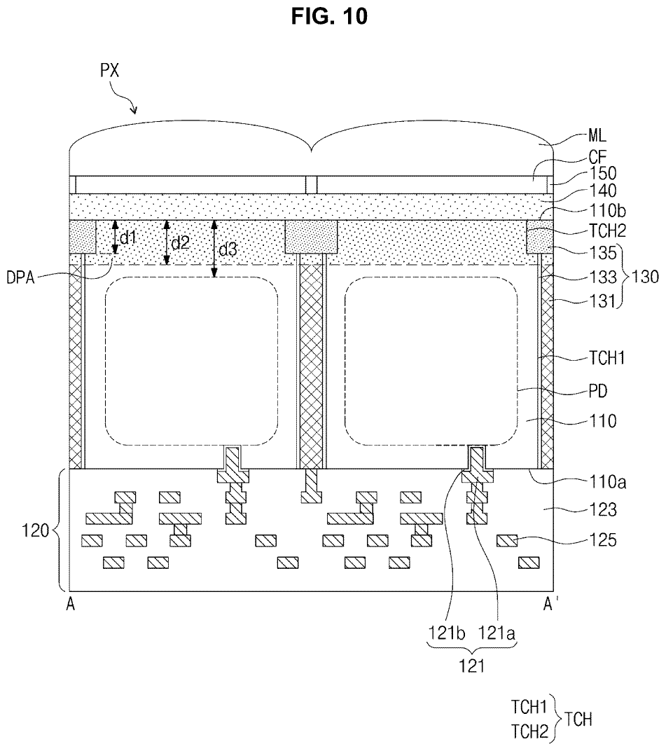

FIGS. 9 and 10 are cross-sectional views, each illustrating an image sensor according to various example embodiments.

Referring to FIGS. 9 and 10, a semiconductor substrate 110 may include an impurity doped region DPA spaced apart from a photoelectric conversion element PD and extending to a predetermined depth from a second surface 110b.

The impurity doped region DPA may correspond to a region doped with impurities of a conductivity type, opposite to a conductivity type of impurities in the photoelectric conversion element PD. In some examples, the impurity doped region DPA may also include impurities of a conductivity type the same as that of the photoelectric conversion element PD, but at a much lower impurity concentration. For example, when the photoelectric conversion element PD is doped with impurities of a second conductivity type, the impurity doped region DPA may be doped with impurities of a first conductivity type opposite to the second conductivity type.

When the photoelectric conversion element PD is a second conductivity type region, for example, an N-type impurity doped region, the impurity doped region DPA may be a first conductivity type region, for example, a P-type impurity doped region. In contrast, when the photoelectric conversion element PD is a first conductivity type region, for example, a P-type impurity doped region, the impurity doped region (DPA) can be a second conductivity type region, for example, an N-type impurity doped region.

The impurity doped region DPA may be formed to a depth, greater than a depth at which the capping layer 135 is formed from the second surface 110b, and to a depth, smaller than a depth at which the photoelectric conversion element PD is formed. For example, when the capping layer 135 is formed to a depth of d1 from the second surface 110b and the impurity doped region DPA is formed to a depth of d2 from the second surface 110b, then d2 may be greater than d1. In some cases, when the photoelectric conversion element PD is disposed at a distance of d3 from the second surface 110b, then d2 may be smaller than d3. For example, the impurity doped region DPA may be formed to a depth, smaller than the depth at which the photoelectric conversion element PD is formed.

According to some example embodiments, the impurity doped region DPA may reduce or prevent pixel defects. According to some example embodiments, to form a capping separation layer 135 covering an upper surface of the conductive separation layer 131 and having a larger width than the conductive separation layer 131, the semiconductor substrate 110 may undergo an etching process of removing a portion of the semiconductor substrate 110 to form a second trench TCH2. After the etching process, a transparent insulating material may fill the second trench TCH2 to form the capping separation layer 135. When such a process is performed, interface defects are likely to occur between the semiconductor substrate 110 and the capping separation layer 135 or the upper insulating layer 140, and etching residues may be produced on the interface between the capping separation layer 135 and the semiconductor substrate 100 within the second trench TCH2. Charges may be accumulated in the interface defects or the residues, and the accumulated charges may cause pixel defects in an image device. For example, the conductive separation layer 131 may be applied with a negative bias. When the conductive separation layer 131 is insufficiently covered with the capping separation layer 135, defects caused by the pixel defects may occur more frequently in a portion adjacent to the photoelectric conversion element PD. However, in some example embodiments, the impurity doped region DPA may be doped with impurities of a conductivity type, opposite to the conductivity type of the photoelectric conversion element PD, to prevent or reduce charges (electrons) accumulated on the interface between the semiconductor substrate 110 and the capping separation layer 135 or charges (electrons) moving from the conductive separation layer 131 from moving to the photoelectric conversion element PD. As a result, the image sensor according to some example embodiments may reduce or prevent the pixel defects.

The above-described image sensor may be implemented in various forms. Hereinafter, detailed examples of pixels in an image sensor according to some example embodiments will be described.

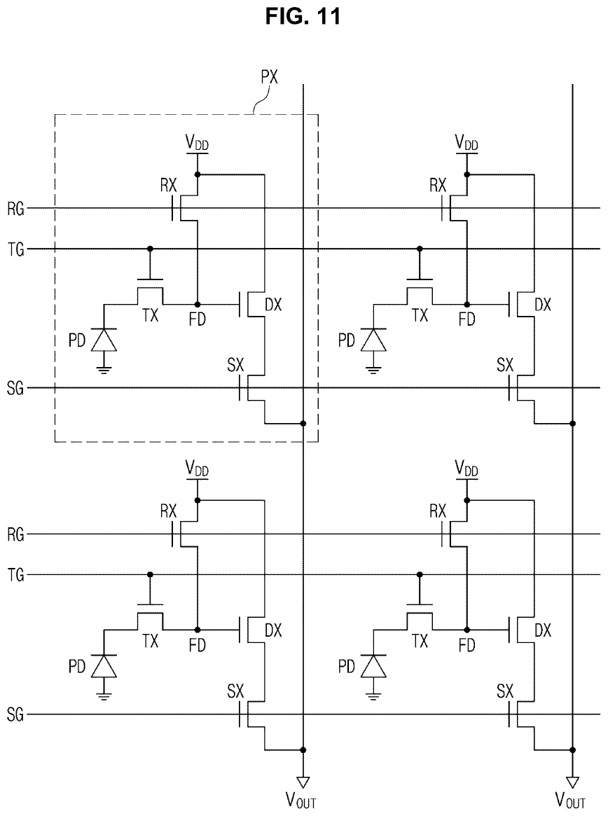

FIG. 11 is a circuit diagram of pixels in an image sensor according to some example embodiments.

Referring to FIG. 11, a pixel array may include a plurality of pixels, and the pixels may be arranged in a matrix form such as a rectangular, e.g., square, form. Each of the pixels may include a transfer transistor TX and logic transistors RX, SX, and DX. The logic transistors may include a reset transistor RX, a select transistor SX, and a source follower transistor DX. The transfer transistor TX may have a transfer gate TG. Each of the pixels may further include a photoelectric conversion element PD and a floating diffusion region FD. The geometric and/or electrical properties of each of the transfer transistor TX and logic transistors RX, SX, and DX may be the same as, or may be different from, each other.

The photoelectric conversion element PD may generate and accumulate photocharges in proportion to the amount of externally incident light. The photoelectric conversion element PD may include a photodiode, a phototransistor, a photogate, a pinned photodiode, or combinations thereof. The transfer transistor TX may transfer the charges, generated by the photoelectric conversion element PD, to the floating diffusion region FD. The floating diffusion region FD may receive the charges generated by the photoelectric conversion element (PD) and may cumulatively store the received charges.

The source follower transistor DX may be controlled depending on the amount of photocharges accumulated in the floating diffusion region FD.

The reset transistor RX may periodically reset the charges accumulated in the floating diffusion region FD. The reset transistor RX may include a drain electrode, connected to the floating diffusion region FD, and a source electrode connected to a power supply voltage V_{DD}. When the reset transistor RX is turned on, the power supply voltage V_{DD} connected to the source electrode of the reset transistor RX may be applied to the floating diffusion region FD. Accordingly, when the reset transistor RX is turned on, the charges accumulated in the floating diffusion region FD may be discharged to reset the floating diffusion region FD.

The source follower transistor DX may serve as a source follower buffer amplifier. The source follower transistor DX may amplify a potential change in the floating diffusion region FD and output the amplified potential change to an output line V_{OUT}.

The select transistor SX may select pixels to be read in units of rows. When the select transistor SX is turned on, the power supply voltage V_{DD} may be applied to the drain electrode of the source follower transistor DX.

The above-described circuit diagram is an example and may vary depending on a pixel structure and a driving method. For example, two or more photoelectric conversion elements may be provided for each pixel. Accordingly, the driving method may also vary appropriately.

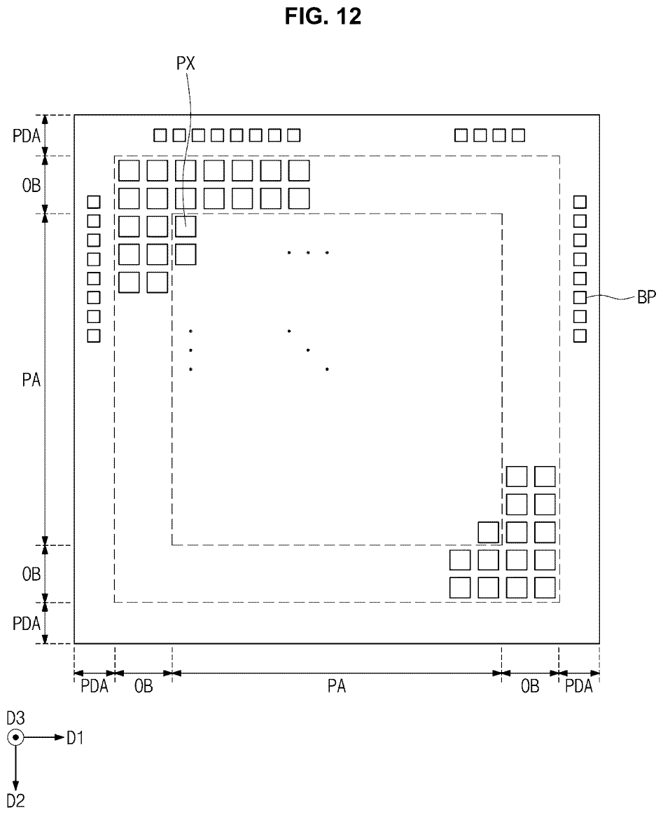

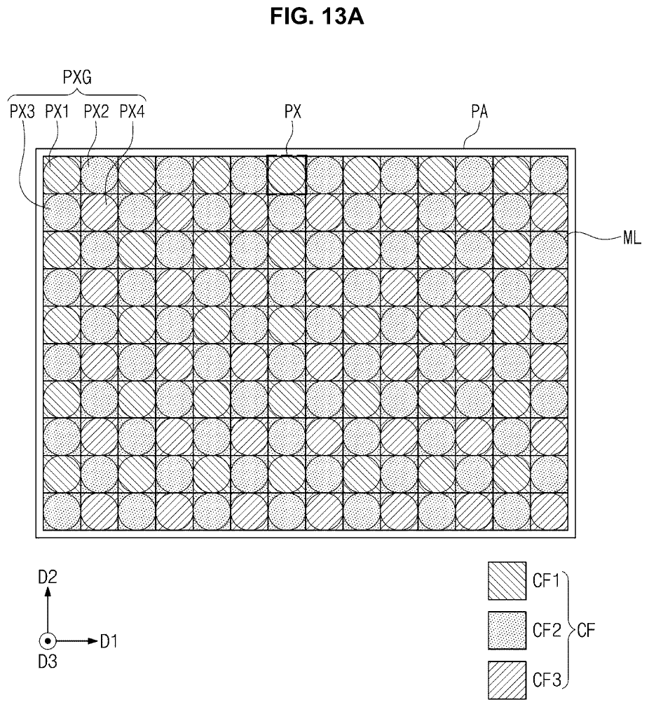

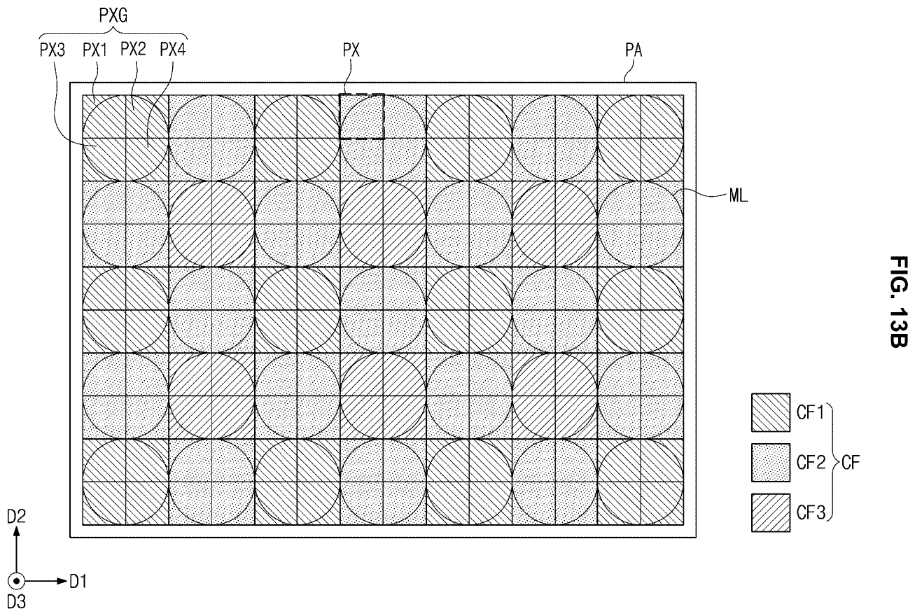

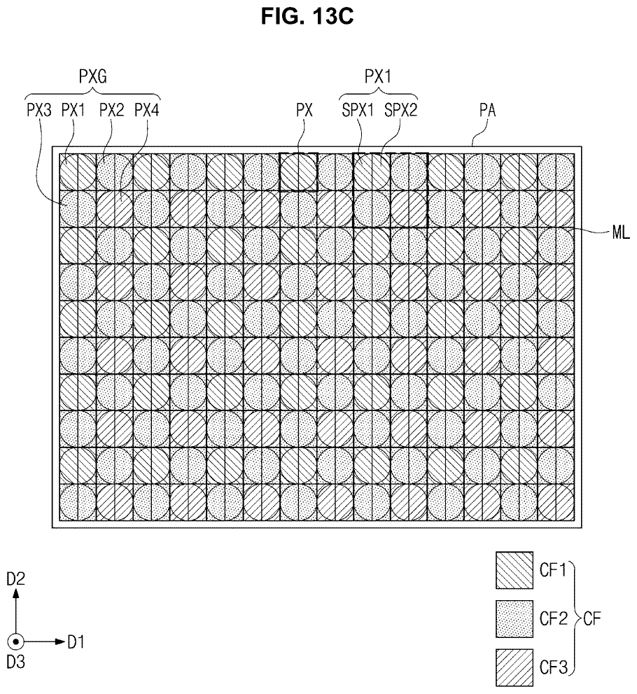

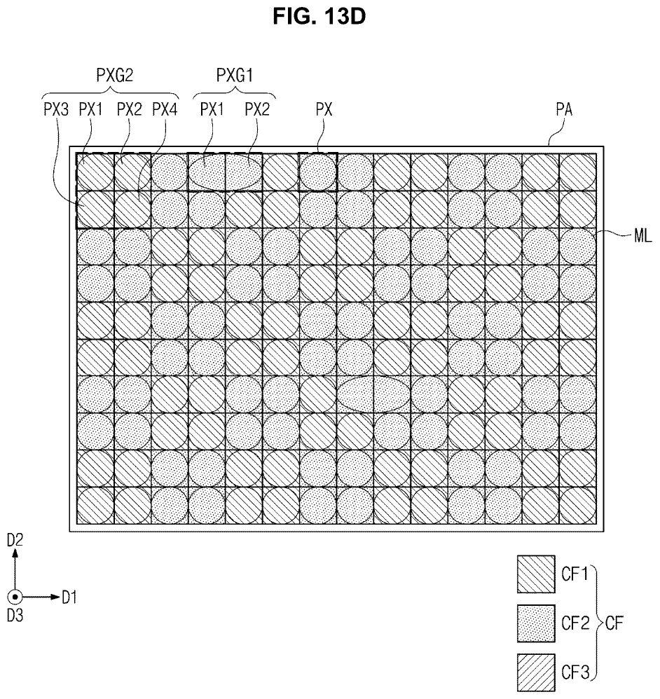

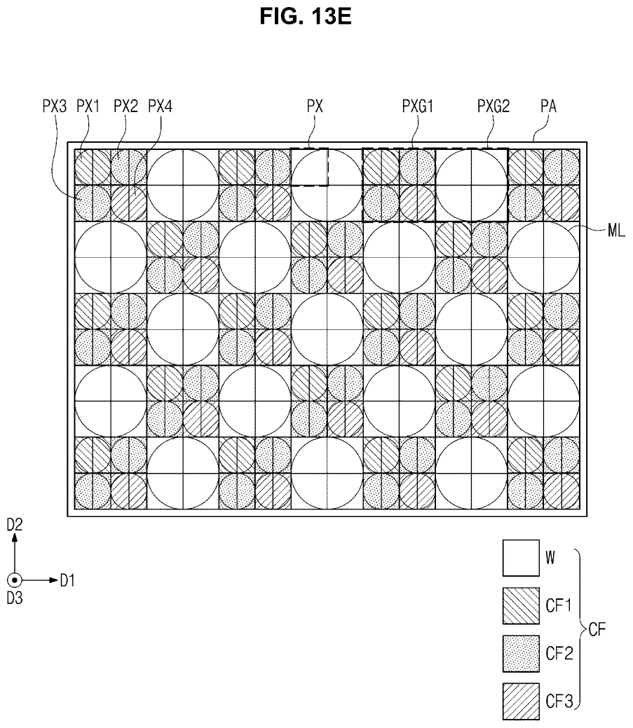

FIG. 12 is a plan view illustrating an image sensor according to some example embodiments, and FIGS. 13A to 13E are conceptual plan views illustrating an array of pixels in a pixel array area of FIG. 12.

Referring to FIG. 12 and FIGS. 13A to 13E, an image sensor may include a pixel array area PA, an optical black area OB, and a pad area PDA when viewed in plan view. The pixel array area PA may be disposed in a central portion of the image sensor when viewed in plan view. The pixel array area PA may be provided with a pixel array in which a plurality of pixels PX are arranged in a matrix.

The pixels PX may output a photoelectric signal from incident light. Pixels may be two-dimensionally arranged while forming rows and columns. The rows may be parallel to a first direction D1, and the columns may be aligned with a second direction D2. The number of rows may be the same as, or different form, the number of columns.

The pad area PDA may be an edge area of the image sensor. When viewed in plan view, the pad area PDA may surround the pixel array area PA. Bonding pads BP may be provided on the pad area PDA. The bonding pads BP may output electrical signals, generated from the pixels PX, to the outside. Alternatively, an external electrical signal and/or a voltage may be transmitted to the pixels PX through the bonding pads BP. Since the pad area PDA is an edge area of the semiconductor substrate 110, the bonding pads BP may be easily connected to the outside. An optical black area OB and the pad area PDA may be provided outside the pixel array area PA.

The optical black area OB may be interposed between the pixel array area PA and the pad area PDA. Similarly to the pixel array (APS) area, the optical black area OB may include both portions with and without photosensitive elements PD.

The image sensor according to some example embodiments may be applied to various structures depending on an array of pixels, a combination of color filters, or the like, in the above-described pixel array area. For example, the image sensor may be applied to various structures such as so-called tetracell, 2PD, and Q-cell, and FIGS. 13A to 13E illustrate a portion of such examples.

Referring to FIG. 13A, a pixel array area PA may be provided with a pixel array including a plurality of pixels PX. Two or more pixels PX may constitute a pixel group PXG. In this case, the pixel array may include a plurality of pixel groups PXG.

In some example embodiments, as an example, a single pixel group PXG may include four pixels PX. For example, the single pixel group PXG may include first to fourth pixels PX1, PX2, PX3, and PX4 arranged in a 2×2 matrix. The single pixel group PXG may be arranged in a matrix along first and second directions D1 and D2 intersecting each other. In the drawings, a direction perpendicular to the first and second directions D1 and D2 may be a third direction D3. A row direction may be the first direction D1, and a column direction may be the second direction D2. The first and second pixels PX1 and PX2 and the third and fourth pixels PX3 and PX4 are arranged sequentially in the first direction D1. In this case, the first and second pixels PX1 and PX2 constitute a first row, and the third and fourth pixels PX3 and PX4 constitute a second row.

One of a plurality of reference colors may be assigned to each of the first to fourth pixels PX1, PX2, PX3, and PX4. The plurality of reference colors may include, for example, red-green-blue (RGB), red-green-blue-white (RGBW), cyan-magenta-yellow (CMY), cyan-magenta-yellow-black (CMYK), red-yellow-blue (RYB), and RGB infrared ray (RGBIR). In some example embodiments, first to third colors may be, for example, a blue color (B), a second color may be a green color (G), and a red color (R), respectively, but are not limited thereto.

Colors of the first to fourth pixels PX1, PX2, PX3, and PX4 may be implemented by color filters CF corresponding to each pixel PX. When an array including the color filters CF corresponding to each pixel PX is referred to as a color filter array, the color filter array may include the first to third color filters CF1, CF2, and CF3 corresponding to each pixel PX. According to some example embodiments, the first to third color filters CF1, CF2, and CF3 may represent blue, green, and red colors, respectively. Alternatively or additionally, the first pixel PX1 may correspond to the first color filter CF1, the second pixel PX2 may correspond to the second color filter CF2, the third pixel PX3 may correspond to the second color filter CF2, and the fourth pixel PX4 may correspond to the third color filter CF3. However, it should be noted that the arrangement of the color filters is not limited thereto and does not restrict the repetitive array structure and pattern of other color filter arrays.

Referring to FIG. 13B, each pixel group PXG may include first to fourth pixels PX1, PX2, PX3, and PX4 arranged in a 2×2 matrix.

One of a plurality of reference colors may be assigned to each pixel group PXG, and each pixel group PXG may have one of the reference colors assigned. For example, a green color may be assigned to a single pixel group PXG. In this case, the first to fourth pixels PX1, PX2, PX3, and PX4 may all have green color filters.

Each pixel group PXG may have a single color. When a plurality of pixel groups PXG are arranged, they may be formed as a Bayer pattern overall. For example, when four pixel groups PXG are arranged to have a 2×2 matrix shape, two pixel groups PXG of a first row may have blue and green colors, respectively, and two pixel groups PXG of a second row may have green and red colors, respectively.

However, it should be noted that the arrangement of the color filters is not limited thereto and does not restrict the repetitive array structure and pattern of other color filter arrays.

As described herein, a single pixel group PXG including the first to fourth pixels PX1, PX2, PX3, and PX4 may be provided with a single microlens. For example, the first to fourth pixels PX1, PX2, PX3, and PX4 within the single pixel group PXG may share the single microlens ML.

As described herein, a single pixel group PXG may include first to fourth pixels PX1, PX2, PX3, and PX4 that are different from each other, and photoelectric conversion signals of photoconductive conversion elements included in each pixel PX may be independently read. A phase difference may be detected based on an arrangement relationship between different photoelectric conversion elements included in each pixel PX to perform autofocusing. The detection of the phase difference may be performed for each direction in which the photoelectric conversion elements within the first to fourth pixels PX1, PX2, PX3, and PX4 are arranged. In the present embodiment, the first to fourth pixels PX1, PX2, PX3, and PX4 are arranged in a first direction D1 and a second direction D2, so that a phase difference may be detected in both horizontal and vertical directions.

Although not described additionally, in some example embodiments, the pixel array may include a plurality of pixel groups PXG and each of the pixel groups PXG may include first to ninth pixels arranged in a 3×3 matrix.

Referring to FIG. 13C, each pixel group PXG may include first to fourth pixels PX1, PX2, PX3, and PX4 arranged in a 2×2 matrix.

As described herein, each of the first to fourth pixels PX1, PX2, PX3, and PX4 may include a first subpixel SPX1 and a second subpixel SPX2. The first and second subpixels SPX1 and SPX2 may be sequentially arranged in a first direction D1.

One of a plurality of reference colors may be assigned to each of the first to fourth pixels PX1, PX2, PX3, and PX4. According to some example embodiments, first to third color filters CF1, CF2, and CF3 may represent blue, green, and red colors, respectively. In addition, the first pixel PX1 may correspond to the first color filter CF1, the second pixel PX2 may correspond to the second color filter CF2, the third pixel PX3 may correspond to the second color filter CF2, and the fourth pixel PX4 may correspond to the third color filter CF3. However, it should be noted that the arrangement of the color filters is not limited thereto and does not restrict the repetitive array structure and pattern of other color filter arrays.

Referring to FIG. 13D, a pixel array area PA may be provided with a plurality of pixel groups having the same shape, and the pixel groups may be arranged in different forms.

As illustrated in FIG. 13D, the pixel group may include first pixel groups PXG1 arranged in a 1×2 matrix and second pixel groups PXG2 arranged in a 2×2 matrix. Some pixels included in the first and second pixel groups PXG1 and PXG2 may be shared with each other, as illustrated.

One of a plurality of reference colors may be assigned to each of the pixel groups PXG1 and PXG2. For example, the first and second pixels PX1 and PX2 in the first pixel group PXG1 may have one of the reference colors assigned. First to fourth pixels PX1, PX2, PX3, and PX4 in the second pixel group may also have one of the reference colors assigned. For example, a green color may be assigned to a single first pixel group PXG1. In this case, both of the first and second pixels PX1 and PX2 may have green color filters. A blue color may be assigned to a single second pixel group PXG2. In this case, the blue color may be assigned to all of the first to fourth pixels PX1, PX2, PX3, and PX4. However, when a single pixel (for example, the second pixel PX2) in the first pixel group PXG1 and an adjacent single pixel (for example, the first pixel PX1) in the second pixel group PXG2 are shared with each other, the shared pixels may have the same color as the remaining pixels (for example, the first pixel PX1) in the first pixel group PXG1.

As described herein, the first and second pixels PX1 and PX2 in each first pixel group PXG1 may share a microlens ML, whereas the first to fourth pixels PX1, PX2, PX3, and PX4 in each second pixel group PXG2 may not share a microlens ML and may each have microlenses ML.

As described above, s pixel array may include pixel groups including two pixels PX1 and PX2 sharing a microlens ML, and all pixels may be two pixels PX1 and PX2 sharing a microlens ML or some pixels may be two pixels PX1 and PX2 sharing a microlens ML. In the above-described embodiments, to perform autofocusing, a single pixel group may include first and second pixels PX1 and PX2 different from each other, and a photoelectric conversion signal of a photoelectric conversion element PD included in each pixel PX be independently read. The autofocusing may be performed by detecting a phase difference using an arrangement relationship between different photoelectric conversion elements PD included in each pixel PX.

Referring to FIG. 13E, a pixel array may include a plurality of pixel groups PXG. The plurality of pixel groups PXG may include first and second pixel groups PXG1 and PXG2. Each first pixel group PXG1 may include first to fourth pixels PX1, PX2, PX3, and PX4 having different colors, and microlenses ML may be individually provided for each of the first to fourth pixels PX1, PX2, PX3, and PX4. Each second pixel group PXG2 may include first to fourth pixels PX1, PX2, PX3, and PX4 having the same color, and a single microlens ML may be provided for the first to fourth pixels PX1, PX2, PX3, and PX4. A color, other than the first to third colors, for example, white may be assigned to the second pixel group PXG2.

The second pixel group PXG2 of the pixel array may be provided with a pixel PX of white color, and thus the amount of light incident on the photoelectric conversion element PD may be significantly increased to improve sensitivity of the image sensor. At the same time, the first pixel group PXG1 may be provided to implement not only image sensing but also autofocusing.

As set forth above, according to various example embodiments, a portion of a device isolation layer near a light incident surface may be used as a transparent insulating material to significantly reduce optical loss. Alternatively or additionally, a semiconductor substrate corresponding to each pixel may be provided to have a convex shape, resulting in improved focusing efficiency of light traveling to a photoelectric conversion element. Alternatively or additionally, an upper surface of a conductive separation layer included in the device isolation layer may be covered with a transparent insulating material to reduce pixel defects.

Accordingly, sensitivity of an image sensor may be improved and photoelectric conversion efficiency may be increased. As a result, a high-quality image sensor may be provided.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While example embodiments have been shown and described above, it will be apparent to those of ordinary skill in the art that modifications and variations could be made without departing from the scope of inventive concepts as defined by the appended claims.

For example, in some example embodiments, an image sensor having microlenses is provided. However, example embodiments may also be applied to an image sensor based on a meta-micro lens (MML) having a nanostructure, rather than a microlens. Alternatively or additionally, example embodiments are not necessarily mutually exclusive with one another. For example, some example embodiments may include one or more features described with reference to one or more figures, and may also include one or more other features described with reference to one or more other figures.

What is claimed is:

1. An image sensor comprising:
a semiconductor substrate comprising a first surface, a second surface, opposing the first surface, and a plurality of pixels, the semiconductor substrate having a first height;
a device isolation layer in a trench penetrating through the first surface and the second surface of the semiconductor substrate and separating the pixels from each other; and
a microlens provided on the second surface,
wherein
the device isolation layer comprises:
a conductive separation layer with a second height smaller than the first height;
a capping separation layer on the conductive separation layer to cover an upper surfaced of the conductive separation layer; and
an insulating liner extending in a direction from the first surface to the second surface, contacting the conductive separation layer, and having a height smaller than the first height and greater than or equal to the second height.

2. The image sensor of claim 1, wherein the capping separation layer has a width, greater than a width of the conductive separation layer.

3. The image sensor of claim 2, wherein the insulating liner has a height, smaller than the first height and greater than the second height.

4. The image sensor of claim 3, wherein the insulating liner comprises a protrusion protruding from an upper surface of the conductive separation layer.

5. The image sensor of claim 1, wherein
each of the pixels comprises a photoelectric conversion element in the semiconductor substrate, and
an upper surface of the semiconductor substrate of each pixel separated by the device isolation layer has a lens shape convex on one side, the lens shape configured to refract a path of light incident on the upper surface of the semiconductor substrate such that the light travels to the photoelectric conversion element.

6. The image sensor of claim 5, wherein the device isolation layer surrounds each pixel, and the upper surface of the semiconductor substrate of each pixel separated by the device isolation layer has an upwardly convex shape.

7. The image sensor of claim 5, wherein the capping separation layer has a staircase shape having a width increased in a direction toward the second surface when viewed in cross-section.

8. The image sensor of claim 5, wherein the capping separation layer comprises an inclined portion having a width increasing in a direction toward the second surface when viewed in cross-section.

9. The image sensor of claim 1, wherein
each pixel comprises a photoelectric conversion element in the semiconductor substrate, and
the photoelectric conversion element includes impurities of a first conductivity type.

10. The image sensor of claim 9, wherein
the semiconductor substrate comprises an impurity doped region from the second surface to a first depth, and the impurity doped region includes impurities of a second conductivity type, opposite to the first conductivity type of the impurities.

11. The image sensor of claim 10, wherein the impurity doped region has a depth, greater than a depth of the capping separation layer.

12. The image sensor of claim 1, wherein the device isolation layer comprises polysilicon including impurities.

13. The image sensor of claim 12, wherein the conductive separation layer is configured to receive a negative bias.

14. The image sensor of claim 1, wherein the capping separation layer has a refractive index, different from a refractive index of the semiconductor substrate.

15. The image sensor of claim 14, wherein the capping separation layer comprises a transparent material.

16. The image sensor of claim 15, wherein the capping separation layer comprises an organic insulating layer or an inorganic insulating layer or both an organic insulating layer and an inorganic insulating layer.

17. The image sensor of claim 16, wherein the capping separation layer comprises at least one of silicon oxide, hafnium oxide, silicon nitride, silicon carbonitride, zirconium oxide, aluminum oxide, titanium oxide, tantalum oxide, lanthanum oxide, praseodymium oxide, cerium oxide, neodymium oxide, promethium oxide, samarium oxide, europium oxide, gadolinium oxide, terbium oxide, dysprosium oxide, erbium oxide, holmium oxide, thulium oxide, ytterbium oxide, lutetium oxide, yttrium oxide, aluminum oxynitride, hafnium oxynitride, or aluminum oxynitride.

18. An image sensor comprising:
a semiconductor substrate comprising a plurality of pixels, a first surface, and a second surface opposing the first surface;
a device isolation layer in a trench penetrating through the first surface and the second surface of the semiconductor substrate and separating the pixels from each other; and
a microlens provided on the second surface,
wherein
each pixel comprises a photoelectric conversion element in the semiconductor substrate, and
an upper surface of the semiconductor substrate of each pixel separated by the device isolation layer has a lens shape convex on one side, the lens shape configured to refract a path of light incident on the upper surface of the semiconductor substrate such that the light travels to the photoelectric conversion element.

19. The image sensor of claim 18, wherein
the device isolation layer comprises:
a conductive separation layer in a portion of the trench;
a capping separation layer on the conductive separation layer to cover an upper surfaced of the conductive separation layer; and
an insulating liner between the conductive separation layer and the semiconductor substrate and comprising a protrusion protruding from an upper surface of the conductive separation layer.

20. An image sensor comprising:
a semiconductor substrate comprising a plurality of pixels each having a photoelectric conversion element, the semiconductor substrate including a first surface, and a second surface opposing the first surface;
a device isolation layer in a trench penetrating through the first surface and the second surface of the semiconductor substrate and separating the pixels from each other; and
a microlens on the second surface,
wherein
the trench defines a first trench having a first width and a second trench having a second width greater than the first width,
the device isolation layer comprises:
a conductive separation layer within the first trench;
a capping separation layer on the conductive separation layer to cover an upper surface of the conductive separation layer and within the second trench; and
an insulating liner extending in a direction from the first surface to the second surface and between the semiconductor substrate and the conductive separation layer, and wherein
an upper surface of the semiconductor substrate of each pixel separated by the device isolation layer has a lens shape convex on one side, the lens shape configured to refract a path of light incident on the upper surface of the semiconductor substrate such that the light travels to the photoelectric conversion element.
